(19) United States
(12) Patent Application Publication
(10) Pub. No.: US 2005/0218491 A1
(43) Pub. Date: Oct. 6, 2005

(54) Circuit component module and method of manufacturing the same

(75) Inventors: Yorihiko Sasaki, Miyagi-ken (JP); Kiyoshi Matsuhashi, Miyagi-ken (JP)

Correspondence Address: BEYER WEAVER & THOMAS LLP, P.O. BOX 70250, OAKLAND, CA, 94612-0250, US

(73) Assignee: ALPS ELECTRIC CO., LTD.

(21) Appl. No.: 11/090,812

(22) Filed: Mar. 25, 2005

(30) Foreign Application Priority Data
Nov. 26, 2004 (JP) 2004-343093
Dec. 17, 2004 (JP) 2004-365968
Mar. 31, 2004 (JP) 2004-101609
Nov. 19, 2004 (JP) 2004-336053

(51) Int. Cl. H01L 23/02

(52) U.S. Cl. 257/678

(57) ABSTRACT

The present invention provides a circuit component module having high precision, reliability, and low manufacturing costs, and a method of manufacturing the same. A circuit component module includes an electronic component, wiring lines formed in a predetermined pattern, and a resin layer for covering some of the wiring lines and the electronic component. The wiring lines are made of, for example, Cu, and are composed of first wiring lines and second wiring lines opposite to the first wiring lines with the resin layer interposed therebetween. The first wiring lines and the second wiring lines are electrically connected to the electronic component at predetermined positions.

### BACKGROUND OF THE INVENTION

1. Field of the Invention

The present invention relates to a thin and lightweight circuit component module having various electronic components therein and to a method of manufacturing the same.

2. Description of the Related Art

For example, in electronic apparatuses, such as mobile phones and personal digital assistants (PDAs), a sheet-shaped circuit component module obtained by integrating a circuit board with various components is used in order to reduce the size, weight and cost thereof. For example, as disclosed in Japanese Patent Application Publication No. 2001-358465 and Japanese Patent Application Publication No. 11-220262, in such a circuit component module, various components are buried in a substrate made of, for example, resin, and a conductive circuit pattern is formed on the surface thereon. Therefore, the circuit component module is formed in a flat board shape having little unevenness, so that it has a small thickness, light weight, and high productivity. Thus, the circuit component module is suitable for component boards of portable electronic apparatuses necessary to have a small size and light weight.

Further, Japanese Patent Application Publication No. 7-79075 discloses, as a means for performing interlayer connection with a through hole provided in a circuit board, a means for pressing copper films against both surfaces of a dielectric substrate having a through hole filled with a metal particle containing resin. Also, Japanese Patent Application Publication No. 7-79075 discloses a current heating means or a supersonic oscillating means, as the pressing means.

Furthermore, Japanese Patent Application Publication No. 2003-152333 discloses a means for pressing a metal layer having an unevenness layer against both surfaces of an insulating substrate having a through hole filled with a conductive resin. In the above-mentioned Japanese Patent Application Publication No. 2003-152333, the unevenness layer should be buried in the through hole at the time of pressing.

However, in the circuit component module disclosed in Japanese Patent Application Publication No. 2001-358465, an organic polymer is coated by, for example, a roll coater, while arranging components, and is then baked to form a contact hole for a wiring line. In this case, unevenness occurs on the surface of the resin, which causes a low component bonding precision. In addition, poor electrical connection occurs due to the residual materials of resin on a chip pad, and bonding portions are easily damaged due to the stress generated between components and resin.

Further, the circuit component module disclosed in Japanese Patent Application Publication No. 11-220262 also has a problem in that bonding portions are easily damaged due to heat or stress generated in a manufacturing process. In addition, since a process of aligning the positions of patterns should be performed many times, the precision of manufacture is deteriorated, and a manufacturing cost increases.

Furthermore, in the circuit board disclosed in Japanese Patent Application Publication No. 7-79075, when the copper films are pressed against both surfaces of the dielectric substrate by a means, such as current heating means, the dielectric substrate is softened and attached to the copper films before the metal particle containing resin filled in the through hole is softened, resulting in the insufficient contact between the metal particle containing resin and the copper films and low reliability.

Moreover, also, in the circuit board disclosed in Japanese Patent Application Publication No. 2003-152333, similar to the circuit board disclosed in Japanese Patent Application Publication No. 7-79075, the dielectric material forming the circuit board is softened before the conductive resin is softened, resulting in the insufficient contact between the conductive resin and the metal film and low reliability.

### SUMMARY OF THE INVENTION

Accordingly, the present invention has been made to solve the above-mentioned problems, and it is an object of the present invention to provide a circuit component module having high precision, high reliability, and low manufacturing costs and a method of manufacturing the same.

In order to achieve the above object, the present invention provides a circuit component module comprising: a resin layer; a component buried in the resin layer; and wiring patterns buried in one surface or both surfaces of the resin layer. Preferably, the circuit component module further comprises a through hole provided in the resin layer and a conductive member for filling the through hole. In addition, the conductive member is preferably a conductive particle containing resin.

Further, the present invention provides a circuit component module comprising: a resin layer; a component buried in the resin layer; and first and second wiring lines buried in one surface or both surfaces of the resin layer, respectively. Preferably, the circuit component module further comprises a through hole provided in the resin layer and a conductive member for filling the through hole. In addition, the conductive member is preferably a conductive particle containing resin. Further, the conductive member is preferably a cylindrical bump formed by laminating a plurality of bumps.

Furthermore, a circuit component module of the present invention comprises a resin layer; and wiring patterns buried in one surface or both surfaces of the resin layer. In the circuit component module, a through hole is provided in the resin layer to pass through both the surfaces thereof, and a conductive particle containing resin is filled in the through hole. In addition, each of the wiring patterns is composed of a plurality of wiring line portions made of conductive metal, and hollowed-out portions are formed in the respective wiring line portions. The conductive particle containing resin is filled in some of the hollowed-out portions arranged on the through hole, and a portion of the resin layer is filled in the hollowed-out portions arranged at the outside of a circumferential edge of the through hole.

According to the above-mentioned structure, since the conductive particle containing resin and the resin layer are filled in the hollowed-out portions provided in the wiring line portions, the bonding strength between the wiring line portions and the conductive particle containing resin and resin layer can be improved, and the contact resistance between the wiring line portions and the conductive particle containing resin is lowered. Thus, it is possible to improve the reliability of a circuit component module.

Moreover, in the above-mentioned circuit component module of the present invention, electronic components are provided in the through hole, and the conductive particle containing resin is formed on terminals of the electronic components. In addition, some of the plurality of wiring line portions provided on the through hole are electrically connected to the terminals of the electronic components through the conductive particle containing resin.

According to the above-mentioned structure, it is possible to reduce the thickness of the circuit component module by providing the electronic components in the through hole. In addition, since the wiring line portions and the terminals of the electronic components are electrically connected to each other through the conductive particle containing resin in the above-mentioned structure, it is possible to improve the reliability of a circuit component module.

Further, in the above-mentioned circuit component module of the present invention, bumps are formed on the wiring line portions provided in the through hole, and the bumps are electrically connected to the terminals of the electronic components.

According to this structure, since the bumps are provided on the wiring line portions, it is possible to reliably perform the connection between the wiring line portions and the electronic components.

Furthermore, the present invention provides a method of manufacturing a circuit component module comprising: a step of forming a resist pattern on one surface of a substrate; a step of coating a metallic material on portions other than the resist pattern; a step of removing the resist to form wiring lines by the coating; a step of mounting a component on the wiring lines; a step of forming a resin layer on the substrate such that the component and the wiring lines are buried in the resin layer; and a step of peeling the substrate from the resin layer.

Moreover, the present invention provides a method of manufacturing a circuit component module comprising: a step of respectively forming resist patterns on surfaces of a first substrate and a second substrate opposite to each other; a step of coating a metallic material on portions other than the resist patterns; a step of removing the resists to form first wiring lines and second wiring lines by the coating; a step of mounting components on the first and second wiring lines, respectively; a step of forming a resin layer between the first and second substrates such that the components and the first and second wiring lines are buried in the resin layer; and a step of peeling the first and second substrates from the resin layer.

Further, the present invention provides a method of manufacturing a circuit component module comprising: a step of forming a wiring pattern in which hollowed-out portions are provided in a plurality of wiring line portions; the wiring pattern forming step including the sub-steps of: forming a sheet layer on one surface of a substrate; forming a resist pattern on the sheet layer; coating a metallic material on portions other than the resist pattern to form the plurality of wiring line portions; and removing the resist pattern; a step of providing a through hole in the resin layer to pass through both surfaces thereof and of filling a conductive particle containing resin in the through hole; a step of pressing the resin layer against the wiring pattern such that the wiring line portions are buried in the resin layer, such that the conductive particle containing resin is filled in the hollowed-out portions provided on the through hole, and such that a portion of the resin layer is filled in the hollowed-out portions provided at the outside of a circumferential edge of the through hole; a step of peeling the substrate and the sheet layer from the resin layer.

According to the above-mentioned structure, since the conductive particle containing resin and the resin layer are filled in the hollowed-out portions provided in the wiring line portions, the bonding strength between the wiring line portions and the conductive particle containing resin and resin layer can be improved, and the contact resistance between the wiring line portions and the conductive particle containing resin is lowered. Thus, it is possible to improve the reliability of a circuit component module. In addition, according to the above-mentioned structure, since a portion of the resin layer is filled in the hollowed-out portions provided at the outside of the circumferential edge of the through hole, it is possible to guide the flow of the resin layer to the hollowed-out portions. In this way, it is possible to prevent the resin layer from flowing up to the inside of the circumferential edge of the through hole, which makes it possible to improve the bonding strength between the conductive particle containing resin and the wiring line portions, without reducing the contact area between the conductive particle containing resin and the wiring line portions.

Furthermore, in the above-mentioned method of manufacturing a circuit component module according to the present invention, in the wiring line forming step, after the resist pattern is formed, an argon plasma is radiated to the one surface of the substrate, and then a metallic material is coated on portions other than the resist pattern to form a plurality of wiring line portions.

According to this structure, since the argon plasma is radiated to the substrate after the resist pattern is formed, it is possible to remove the residual material of the resist remaining on the portions where the wiring lines are formed, and to prevent the cutting of the wiring line portions. In addition, it is possible to improve the adhesion between the substrate and the wiring line portions and to previously prevent the generation of defects in the pressing step and the peeling step.

Moreover, preferably, the method of manufacturing a circuit component module according to the present invention further comprises a step of etching the sheet layer transferred onto the resin layer to remove it after the peeling step.

Further, in the above-mentioned method of manufacturing a circuit component module according to the present invention, in the resin layer forming step, electronic components are provided in the through hole of the resin layer, and the conductive particle containing resin is formed on terminals of the electronic components. In the pressing step, some of the plurality of wiring line portions provided on the through hole are electrically connected to the terminals of the electronic components through the conductive particle containing resin interposed therebetween.

According to this structure, it is possible to reduce the thickness of the circuit component module by providing the electronic components in the through hole. In addition, since the wiring line portions and the terminals of the electronic components are electrically connected to each other through the conductive particle containing resin interposed therebetween as described above, it is possible to improve the reliability of the circuit component module.

Furthermore, in the above-mentioned method of manufacturing a circuit component module according to the present invention, bumps are formed on the wiring line portions provided in the through hole, and the bumps are electrically connected to the terminals of the electronic components.

According to this structure, since the bumps are provided on the wiring line portions, it is possible to reliably perform the electric connection between the wiring line portions and the electronic components.

### BRIEF DESCRIPTION OF THE DRAWINGS

FIG. 1 is a cross-sectional view illustrating an example of a circuit component module according to a first embodiment of the present invention;

FIG. 2 is a cross-sectional view illustrating a method of manufacturing the circuit component module according to the first embodiment of the present invention;

FIG. 3 is a cross-sectional view illustrating the method of manufacturing the circuit component module according to the first embodiment of the present invention;

FIG. 4 is a cross-sectional view illustrating the method of manufacturing the circuit component module according to the first embodiment of the present invention;

FIG. 5 is a flow diagram illustrating a method of manufacturing a circuit component module according to a second embodiment of the present invention;

FIG. 6 is a plan view schematically illustrating the shape of a wiring pattern.

FIG. 7 is a flow diagram illustrating the method of manufacturing the circuit component module according to the second embodiment of the present invention;

FIG. 8 is a flow diagram illustrating the method of manufacturing the circuit component module according to the second embodiment of the present invention;

FIG. 9 is a flow diagram illustrating a method of manufacturing a circuit component module according to a third embodiment of the present invention;

FIG. 10 is an enlarged cross-sectional view schematically illustrating a wiring pattern provided in the circuit component module according to the third embodiment;

FIG. 11 is a flow diagram illustrating the method of manufacturing the circuit component module according to the third embodiment of the present invention; and

FIG. 12 is a flow diagram illustrating the method of manufacturing the circuit component module according to the third embodiment of the present invention.

### DESCRIPTION OF THE PREFERRED EMBODIMENTS

### First Embodiment

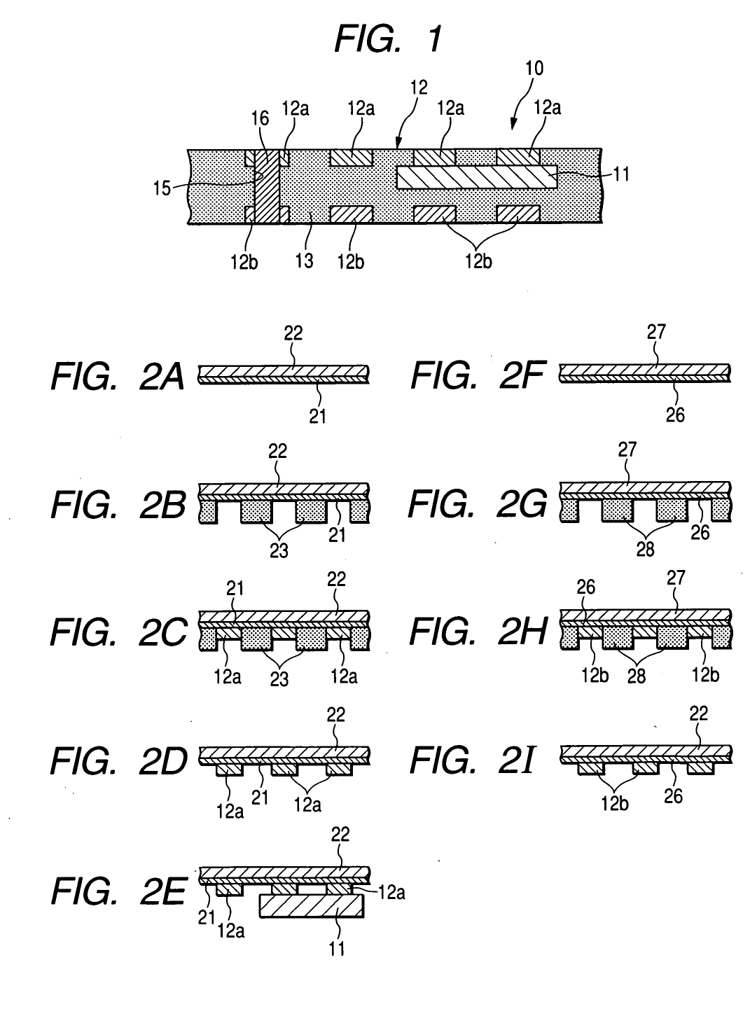

Hereinafter, a first embodiment of the present invention will be described with reference to the accompanying drawings. FIG. 1 is a cross-sectional view illustrating an example of the structure of a circuit component module according to the present embodiment. A circuit component module 10 is, for example, a thin component mounting circuit board having an overall thickness of about 0.3 mm. The circuit component module 10 has an electronic component 11, wiring lines 12 formed in a predetermined pattern, and a resin layer 13 partially covering the electronic component 11 and the wiring lines 12.

The wiring lines 12 are composed of first wiring lines 12a and second wiring lines 12b opposite to the first wiring lines 12a with the resin layer 13 interposed therebetween, and may be made of a metallic material, such as, Cu. The first wiring lines 12a and the second wiring lines 12b are electrically connected to the electronic component 11 at predetermined positions.

The resin layer 13 may be made of, for example, a thermosetting resin having an insulating property. In addition, a through hole 15 is formed in the resin layer 13, and a conductive member 16 is filled in the through hole 15. The conductive member 16 functions to electrically connect the first wiring line 12a to the second wiring line 12b, and may be made of, for example, a conductive particle containing resin.

According to the circuit component module 10 having the above-mentioned structure, since the electronic component 11 is covered with the resin layer 13, the electronic component 11 is protected from the external environment. Further, since the electronic component 11 is arranged between the first wiring lines 12a and the second wiring lines 12b, it is possible to reduce the thickness and weight of the circuit component module 10. In addition, when the circuit component module 10 is used as a component circuit board for a portable electronic apparatus, it is possible to reduce the size and weight of the potable electronic apparatus.

Next, a method of manufacturing the circuit component module having the above-mentioned structure will be described below. In the method of manufacturing the circuit component module 10, as shown in FIG. 2A, a first substrate 22 having a sheet layer 21 on the surface thereof is prepared. Then, a resist layer 23 having a pattern corresponding to the first wiring lines 12a is formed on the sheet layer 21 (see FIG. 2B).

Next, a metallic material, such as Cu, is deposited on portions of the sheet layer 21 exposed through the resist layer 23 to form the first wiring lines 12a (see FIG. 2C). Subsequently, when the resist layer 23 is removed, the first wiring lines 12a are formed on the sheet layer 21 of the first substrate 22, as shown in FIG. 2D. Then, the electronic component 11 is mounted on the first wiring lines 12a (FIG. 2E).

Meanwhile, a second substrate 27 having a sheet layer 26 on the surface thereof is prepared (see FIG. 2F). Then, in the same manner as used for the first substrate 22, a resist layer 28 having a pattern corresponding to the second wiring lines 12b is formed on the sheet layer 26 (see FIG. 2G).

Next, a metallic material, such as Cu, is deposited on portions of the sheet layer 26 exposed through the resist layer 28 to form the second wiring lines 12b (see FIG. 2H). Subsequently, when the resist layer 28 is removed, the second wiring lines 12b are formed on the sheet layer 26 of the second substrate 27, as shown in FIG. 2I.

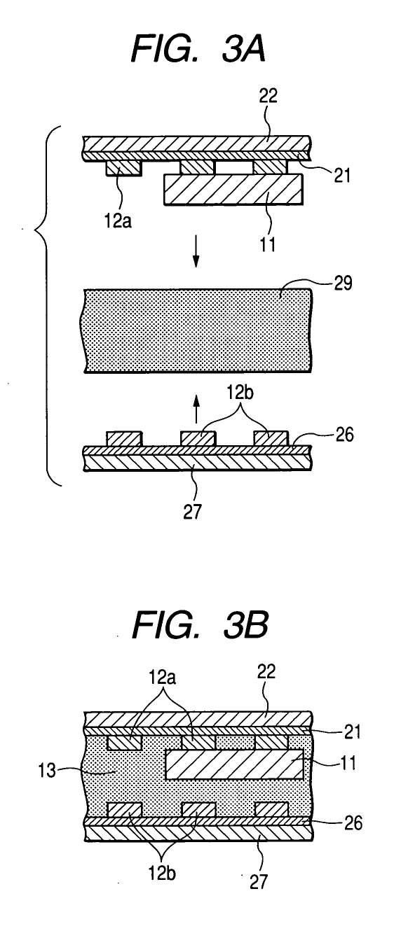

As shown in FIG. 3A, the first substrate 22 and the second substrate 27 are arranged such that the sheet layer 21 and the sheet layer 26 are opposite to each other with a resin layer 29 interposed between the first and second substrates 22 and 27, and these three members are bonded to each other by thermal pressing. Then, as shown in FIG. 3B, the resin layer 29 changes to a liquid state by the thermal pressing, so that a resin layer 13 having the electronic component 11, the first wiring lines 12a and the second wiring lines 12b therein is formed.

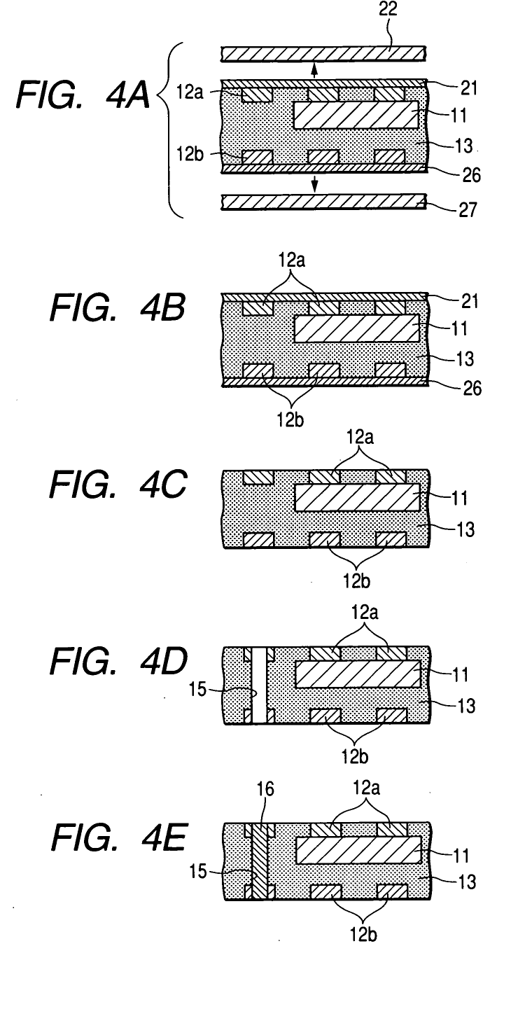

Next, as shown in FIG. 4A, the first substrate 22 and the second substrate 27 are respectively peeled off from the sheet layer 21 and the sheet layer 26 (see FIG. 4B). Then, the sheet layers 21 and 26 are removed by etching, respectively (see FIG. 4C). In this way, both surfaces of the resin layer 13 and one surface of each of the first and second wiring lines 12a and 12b are exposed.

Successively, a through hole 15 is formed in the resin layer 13 at a predetermined position (see FIG. 4D), and a conductive member, for example, a conductive particle containing resin, is filled in the through hole 15 to electrically connect the first wiring line 12a to the second wiring line 12b at a predetermined position. In this way, the circuit component module 10 according the present invention shown in FIG. 3E is completed.

Further, as the conductive member 16 filled in the through hole 15, a cylindrical bump formed by laminating a plurality of bumps may be used instead of the conductive particle containing resin. The cylindrical bump is preferably made of a metallic material, such as Au or Ag.

According to the circuit component module manufacturing method of the present invention having the above-mentioned structure, after wiring lines and components are respectively mounted on two substrates, a resin layer is formed, and then the two substrates are removed. Therefore, unevenness is hardly generated on the surface of the resin layer, which makes it possible to maintain high precision in bonding components. In addition, since a process of aligning the positions of wiring circuit patterns is not needed, it is possible to improve the precision of manufacture and to reduce manufacturing costs, thereby achieving a circuit component module having a low manufacturing cost.

### Second Embodiment

Next, an electronic component module according to a second embodiment of the present invention and a method of manufacturing the same will be described below.

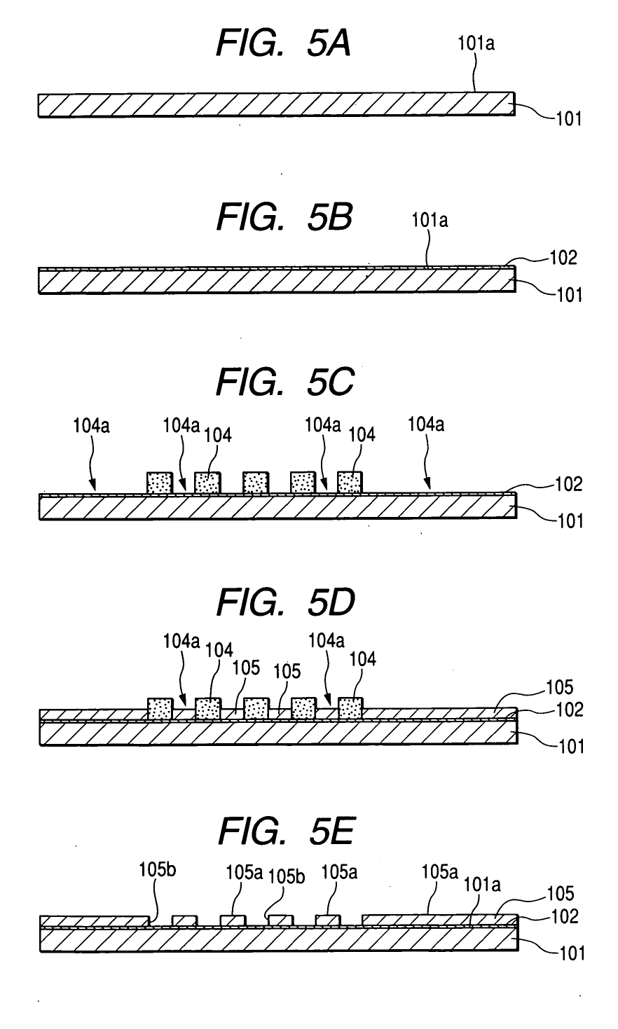

The method of manufacturing the electronic component module according to the present embodiment schematically comprises a wiring line portion forming process of forming a wiring line portion on a substrate, a resin layer forming process, a pressing process of burying the wiring line portion in the resin layer and of pressing it against the resin layer, and a peeling process of peeling the substrate from the resin layer. Hereinafter, the respective processes will be described with reference to the drawings. FIGS. 5 to 8 are flow diagrams illustrating manufacturing processes of the electronic component module according to the present embodiment. These drawings are used for illustrating the electronic component module of the present embodiment and the method of manufacturing the same, and the sizes, thicknesses, or dimensions of the respective components shown in the drawings are not necessarily equal to the actual sizes, thicknesses, or dimensions of the components in the electronic component module.

[Wiring Line Forming Process]

Hereinafter, the wiring line forming process will be described with reference to FIG. 5. In the wiring line forming process, first, a substrate 101 shown in FIG. 5A is prepared, and a sheet layer 102 is formed on at least one surface 101a of the substrate 101, as shown in FIG. 5B. Here, for example, a laminated structure consisted of a zinc oxide layer formed on the one surface 101a with a thickness of 50 nm to 500 nm and a copper layer formed on the zinc oxide layer with a thickness of about 2 μm can be used as the sheet layer 102. Also, the sheet layer 102 may be formed on both surfaces of the substrate 101 as well as the one surface 101a thereof. When the sheet layer 102 is formed on both surfaces of the substrate 101, the detachability between the substrate 101 and a wiring pattern, which will be described later, can be improved. The zinc oxide layer can be formed by, for example, an electroless plating method in a state in which it is soaked in a plating bath containing a zinc oxide. Also, the copper layer can be formed by the electroless plating method.

Further, it is preferable that a silicon oxide be formed on the entire surface of the substrate 101 in order to improve the adhesion of the substrate to the zinc oxide layer constituting the sheet layer and to reuse the substrate. As an example of the substrate 101, a glass substrate having a silicon oxide as the main ingredient, a silicon substrate whose entire surface is covered with a silicon oxide layer by a thermal oxidation method or a thermal CVD method, a resin substrate whose entire surface is covered with a silicon oxide layer by, for example, a sputtering method, or a dielectric substrate can be used. In addition, a dopant, such as B, P, or As, may be added to the silicon substrate. Further, a flexible substrate may be used as the resin substrate. In this case, since a long resin substrate can be rolled, the resin substrate can be continuously manufactured, thereby improving the productivity thereof. The thickness of the substrate 101 is not limited to a specific value, but may be, for example, in the range of 30 μm to 300 mm.

Then, as shown in FIG. 5C, a patterned resist layer 104 (resist pattern) having a plurality of resist removing portions 104a is formed on the sheet layer 102. More specifically, a dry film or photosensitive resin film (hereinafter, referred to as a resist layer) having, for example, a thickness of about 10 μm is formed on the entire surface of the sheet layer 102, and then a mask is covered thereon. Then, exposure and development are sequentially performed thereon to form the resist removing portions 104a corresponding to the pattern of the mask. In this way, the patterned resist layer 104 having the resist removing portions 104a is formed.

Furthermore, after the patterned resist layer 104 is formed, a residual material of the photosensitive resin film or dry film may remain on the resist removing portions 104a. When the residual material remains, the wiring patterns to be formed in the next stage may be cut, or the adhesion between the wiring pattern and the sheet layer 102 may be lowered, so that defects may occur in a pressing process and a peeling process to be performed in the subsequent stages. Therefore, in order to completely remove the residual material, after the patterned resist layer 104 is formed, argon plasma is radiated to the resist removing portions 104a, or the surface of the sheet layer exposed to the resist removing portions 104a is lightly etched. For example, the argon plasma is preferably radiated under the conditions, such as a plasma power of about 500 W, an atmosphere pressure of 10 Pa, an argon flux of 50 sccm, and a radiation time of 30 seconds. In addition, the process of lightly etching the surface of the sheet layer is preferably performed for 30 seconds using an etchant composed of a 10% acetic aqueous solution. Such a process enables the adhesion strength between the sheet layer 102 and the wiring pattern to be greater than 3 N/cm.

Next, as shown in FIG. 5D, a wiring pattern 105 made of Cu is formed on the resist removing portions 104a by a plating method. More specifically, for example, a direct current is applied to the sheet layer 102 while a plating solution containing copper sulfate is being brought into contact with the sheet layer 102 in the resist removing portions 104a, thereby growing a Cu film. The thickness of the wiring pattern 105 is preferably smaller than that of the patterned resist layer 104, and may be, for example, about 5 μm.

Next, as shown in FIG. 5E, the patterned resist layer 104 is removed by wet etching. In this way, the sheet layer 102 and the wiring pattern 105 are formed on the one surface 101a of the substrate 101.

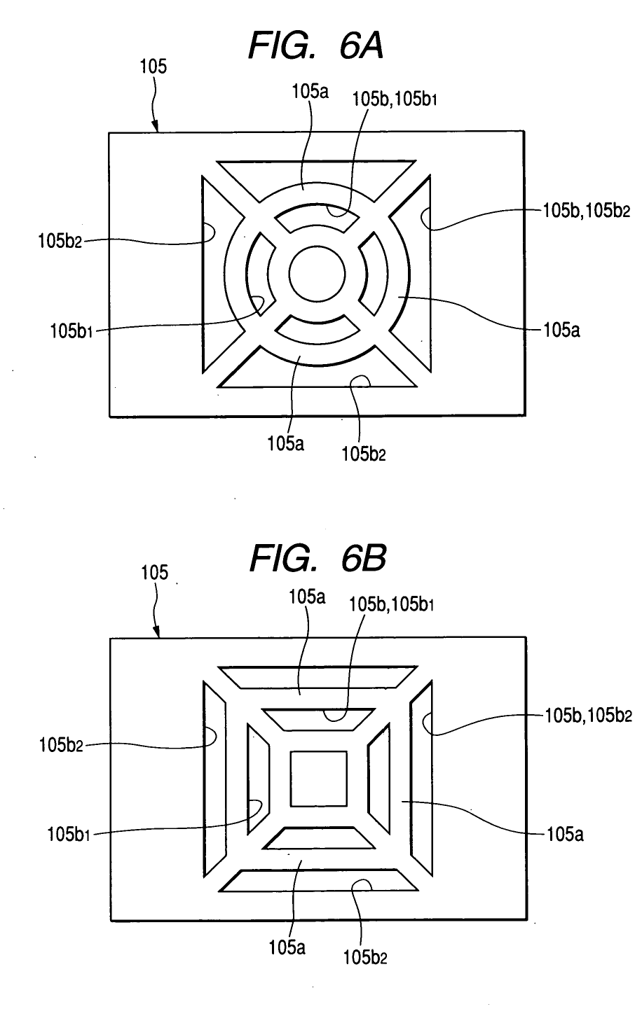

FIG. 6 is a plan view schematically illustrating the wiring pattern 105. As shown in FIGS. 5E and 6A, the wiring pattern 105 includes a plurality of wiring line portions 105a and hollowed-out portions 105b provided adjacent to the wiring line portions 105a. The wiring line portions 105a are formed by plating Cu on the resist removing portions 104a of the patterned resist layer 104. In addition, the hollowed-out portions 105b are provided at positions where Cu is not coated by the patterned resist layer 104. The average line width of the wiring line portions 105a is preferably set in the range of 10 μm to 20 μm. In addition, the average line width of the hollowed-out portions 105b is preferably set in the range of 10 μm to 20 μm.

Further, the plane shape of the wiring pattern 105 is not limited to the shape shown in FIG. 6A, and may have the shape shown in FIG. 6B.

[Resin Layer Forming Process]

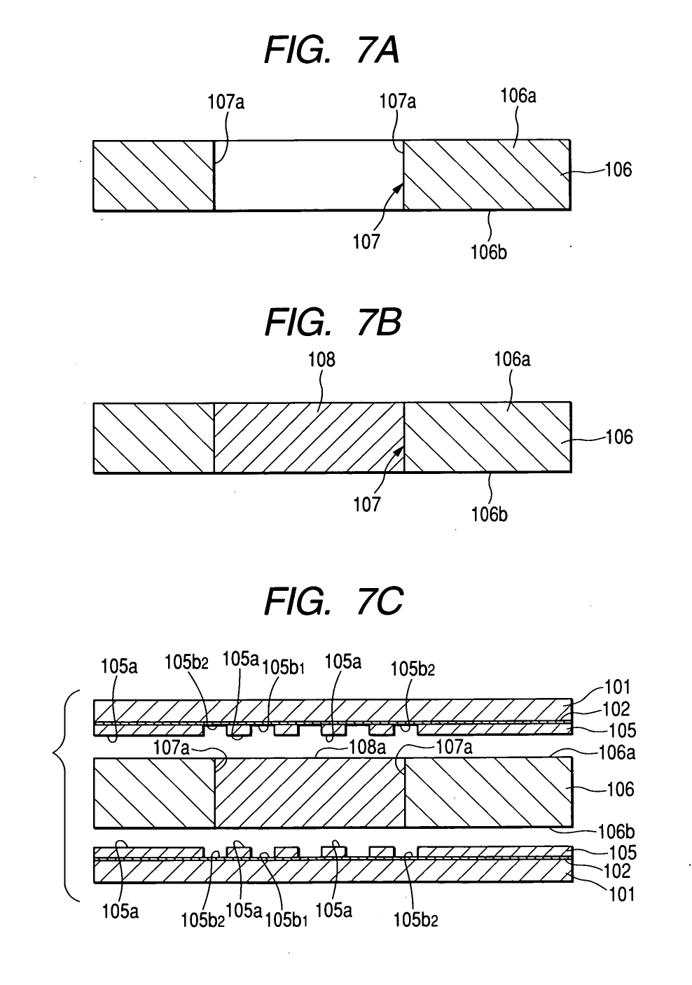

Next, the resin layer forming process will be described with reference to FIG. 7. In the resin layer forming process, as shown in FIG. 7A, first, a resin layer 106 is prepared, and a through hole 107 is provided in the resin layer 107 so as to pass through both surfaces 106a and 106b thereof. The through hole 107 may be formed in a polygonal shape including a circular shape, an elliptical shape, a triangular shape, and a rectangular shape in plan view. The through hole 107 preferably has such a size, as the maximum size, that, when the wiring pattern 105 previously formed overlaps the through hole 107, a circumferential edge 107a for defining the through hole 107 partially overlaps the hollowed-out portions 105b of the wiring pattern 105. The through hole 107 can be formed by, for example, a punching process using a mold or laser machining. In addition, the resin layer 106 can be composed of a plate made of a thermoplastic resin, such as an epoxy resin, a glass epoxy resin, or a polyester resin, with a thickness of about 50 μm.

Next, as shown in FIG. 7B, a conductive particle containing resin 108 is filled in the through hole 107 of the resin layer 106. The conductive particle containing resin 108 is a paste-state resin obtained by dispersing conductive particles of a metallic material, such as Au, Ag, or Al, in, for example, an epoxy resin.

In this way, the resin layer 106 is formed in which the conductive particle containing resin 108 is filled in the through hole 107.

[Pressing Process]

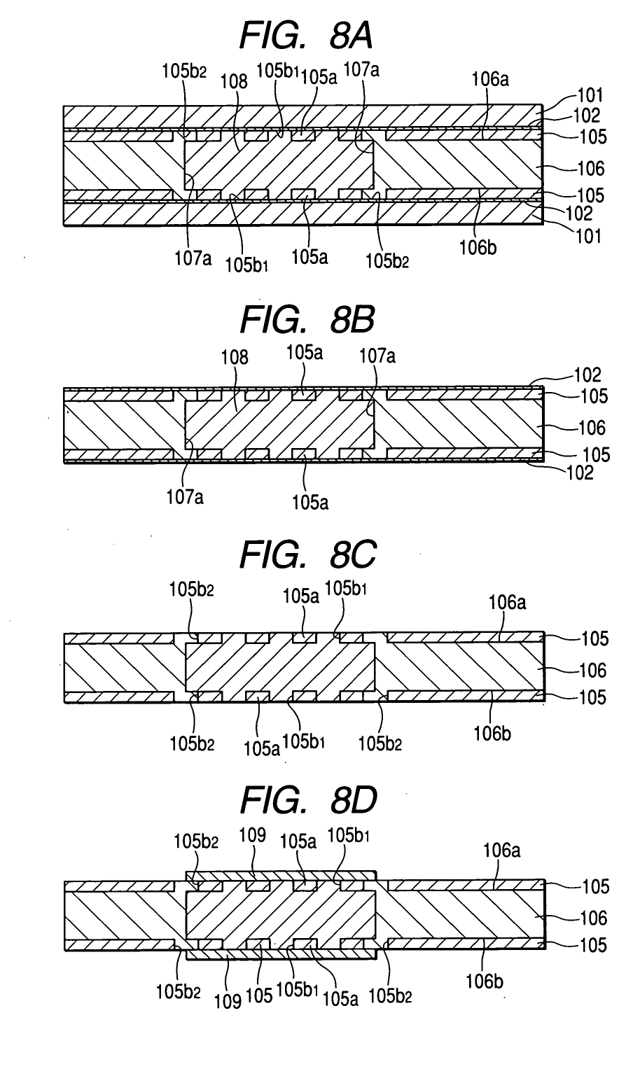

Next, the pressing process will be described with reference to FIGS. 7 and 8. In the pressing process, first, as shown in FIG. 7C, two substrates 101 each having the wiring pattern 105 previously formed thereon are respectively arranged at both sides of the one surface 106a and the other surface 106b of the resin layer 106. At that time, the substrates 101 are arranged such that the hollowed-out portions 105b of the wiring pattern 105 of each substrate substantially overlap the portion where the conductive particle containing resin 108 is filled. More specifically, hollowed-out portions 105b₁ of the hollowed-out portions 105b positioned substantially at the center of FIG. 7C are provided at the more inner side than the circumferential edge 107a of the through hole. In addition, hollowed-out portions 105b₂ positioned at the outer circumferential side of the hollowed-out portions 105b₁ are provided to place across the inner side and the outer side of the circumferential edge 107a of the through hole.

Then, as shown in FIG. 8A, both the substrates 101 are thermally pressed against each other with the resin layer 106 interposed therebetween in the thickness direction thereof. The resin layer 106 is transformed by the thermal pressing, so that the wiring patterns 105 are buries in the one surface 106a and the other surface 106b, respectively. At that time, a portion of the conductive particle containing resin 108 and a portion of the resin layer 106 are filled in the hollowed-out portions 105b of each wiring pattern 105. The temperature at the time of the thermal pressing is preferably in the range of 140 to 180° C. according to the material of the resin layer 106. The pressure of the thermal pressing is preferably in the range of 15 to 25 Pa. In addition, the thermal pressing is preferably performed for about 30 to 50 seconds.

Referring to FIG. 8 again for the detailed explanation, the substrates 101 are pressed against the resin layer 106, which causes the resin layer 106 to be transformed into a thin plate. Accordingly, the conductive particle containing resin 108 is filled in the hollowed-out potions 105b₁ positioned substantially at the center of the drawing. Meanwhile, a portion of the resin layer 106 is filled in the hollowed-out portions 105b₂ positioned at the outside of the hollowed-out portions 105b₁. When the resin layer 106 is made of a glass epoxy resin, only the epoxy resin is extruded from the resin layer and is then filled in the hollowed-out portions 105b₂. The reason why a portion of the resin layer 106 is filled in the hollowed-out portions 105b₂ is that the resin layer is softened when the substrates 101 are pressed, and that a portion of the resin layer flows into the hollowed-out portion 105b₂ prior to the conductive particle containing resin 108.

[Peeling Process and Etching Process]

Next, the peeling process will be described with reference to FIG. 8. In the peeling process, as shown in FIG. 8B, stress is applied between the resin layer 106 and the respective substrates 101 to peel off the substrates 101 from the resin layer 106. When, the respective substrates 101 are peeled off from the sheet layers 102, the sheet layers 102 and the wiring patterns 105 are transferred to the resin layer 106. In addition, residual materials of the sheet layers 102 on the peeled substrates that are not transferred are removed by acid or alkali, so that the peeled substrates can be reused.

The substrates 101 are peeled off from the sheet layer 102 according to the following mechanism.

That is, when the substrates 101 are peeled off from the resin layer 106, tensile stress is applied to the sheet layer 102 in the thickness direction thereof. At that time, the wiring pattern 105 is bonded to the copper layer constituting the sheet layer 102, and is then buried in the resin layer 105 to be fixedly bonded to the resin layer 106, so that strong tensile stress is applied to the resin layer 106. In this way, the sheet layer 102 and the wiring pattern 105 can be transferred to the resin layer 106. In addition, the shear stress strained to the wiring pattern 105 at the time of peeling is applied to the copper layer constituting the sheet layer 102. However, since the zinc oxide layer is formed on the copper layer as a base layer, the copper layer is cleanly peeled off from the substrate 101 together with the zinc oxide layer, without being torn. In addition, since the zinc oxide layer is formed with a thickness of 50 nm to 500 nm, the zinc oxide layer has high film strength. Therefore, the zinc oxide layer is also cleanly peeled off from the substrate 101 without being torn.

Subsequently, as shown in FIG. 8C, the sheet layer 102 transferred onto the resin layer 106 is removed by wet etching. In addition, for example, a persulfuric aqueous solution can be used as an etchant. At the time of etching, the wiring pattern 105 is also etched a little, but the line width of the wiring line portions 105 is not reduced. The reason is that, since most of the wiring pattern 105 is buried in the resin layer 106 and the conductive particle containing resin 108, a small area of the wiring pattern 105 is exposed, so that the wiring pattern 105 is protected by the resin layer 106 and the conductive particle containing resin 108. Since the wiring pattern 105 is protected by the resin layer 106, the etching of the wiring pattern 105 by the etchant is prevented, so that the reduction of the line width of the wiring pattern can be prevented. Therefore, it is possible to realize a line and space (L/S) of 10 μm/10 μm, which has not been achieved in the related art.

Finally, as shown in FIG. 8D, a conductive resin layer 109 is formed to cover the hollowed-out portions 105b of the wiring pattern 105.

In this way, the circuit component module 100 of the present embodiment is manufactured.

[Circuit Component Module]

The circuit component module 100 shown in FIG. 8D includes the resin layer 106 and the wiring patterns 105 respectively buried in the one surface 106a and the other surface 106b of the resin layer 106. The through hole 107 is provided in the resin layer 106, and the conductive particle containing resin 108 is filled in the through hole 107. In addition, each wiring pattern 105 is composed of a plurality of wiring line portions 105a made of Cu, and the hollowed-out portions 105b are formed in the respective wiring line portions 105a. Further, the conductive particle containing resin 108 is filled in the hollowed-out portions 105b₁ of the hollowed-out portions 105b provided on the through hole 107, and a portion of the resin layer 106 is filled in the hollowed-out portions 105b₂ provided at the outside of the circumferential edge 107a of the through hole 107.

According to the above-mentioned circuit component module 100, since the conductive particle containing resin 108 and the resin layer 106 are filled in the hollowed-out portions 105b provided in the wiring line portions 105a, the bonding strength between the wiring line portions 105a and the conductive particle containing resin 108 and resin layer 105 is improved, and the contact resistance between the wiring line portions 105a and the conductive particle containing resin 108 is reduced. Thus, it is possible to improve the reliability of the circuit component module 100.

Further, according to the method of manufacturing the circuit component module, a portion of the resin layer 106 is filled in the hollowed-out portions 105b₂ provided at the outside of the circumferential edge 107a of the through hole 107, which allows the resin layer 106 to flow into the hollowed-out portions 105b₂ provided at the outside of the circumferential edge. Therefore, it is possible to prevent the resin layer 106 from flowing inside the circumferential edge 107a of the through hole, which makes it possible to improve the bonding strength between the conductive particle containing resin 108 and the wiring line portions 105a, without decreasing the contact area between the conductive particle containing resin 108 and the wiring line portions 105a.

Furthermore, according to the above-mentioned manufacturing method, argon plasma is radiated onto the substrate 101 on which the patterned resist layer 104 is formed, to remove the residual material of the resist. In addition, with this structure, it is possible to prevent the cutting of the wiring line portions 105a and to improve the adhesion between the substrate 101 and the wiring line portions 105a, which makes it possible to previously prevent the generation of defects in the pressing process and the peeling process.

### Third Embodiment

Next, an electronic component module according to a third embodiment of the present invention and a method of manufacturing the same will be described.

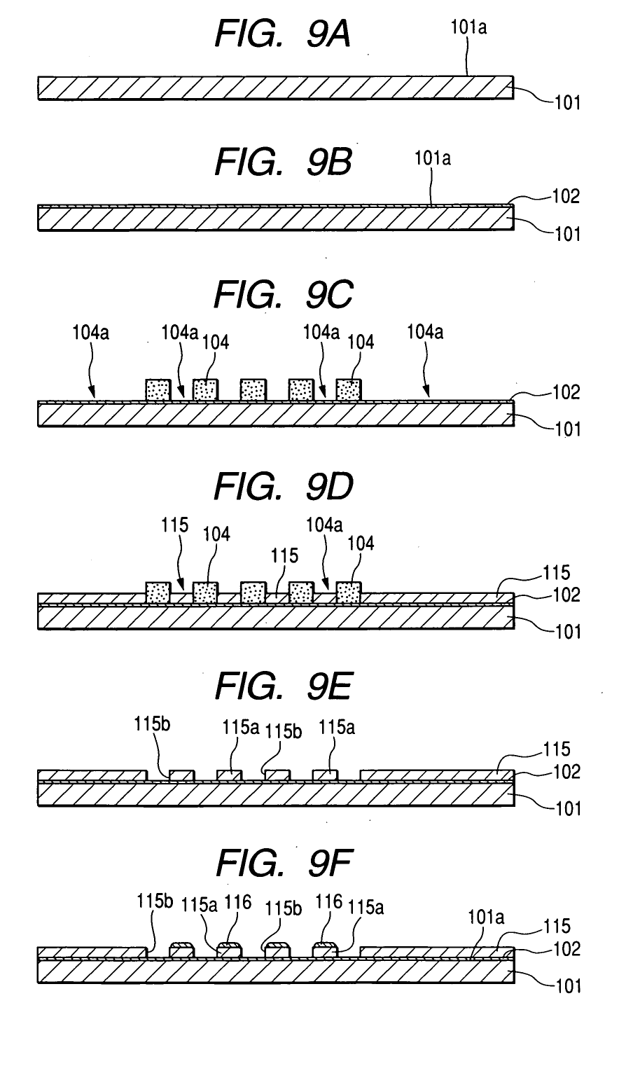

The method of manufacturing the electronic component module according to the present embodiment schematically comprises a wiring line forming process for forming wiring line portions on a substrate, a resin layer forming process, a pressing process for pressing the wiring line portions against the resin layer to bury the wiring line portions in the resin layer, and a peeling process for peeling the substrate from the resin layer, similar to the manufacturing method in the second embodiment. Hereinafter, the respective processes will be described with reference to the drawings. FIGS. 9 to 12 are flow diagrams illustrating the method of manufacturing the electronic component module according to the present embodiment. In addition, in these drawings for describing the electronic component module according to the present embodiment and the method of manufacturing the same, the size, thickness, and dimension of each component shown in these drawings are not necessarily equal to the actual size, thickness, and dimension of each component of the electronic component module. In addition, in FIGS. 9 to 12, among substrates, films, and other members, the same components as those in FIGS. 5 to 8 have the same reference numerals, and thus the description thereof will be omitted.

[Wiring Line Forming Process]

Hereinafter, the wiring line forming process will be described with reference to FIG. 9. First, as shown in FIG. 9A, a substrate 101 is prepared, and then a sheet layer 102 is formed on at least one surface 101a of the substrate 101, as shown in FIG. 9B.

Then, as shown in FIG. 9C, a patterned resist layer 104 (resist pattern) having a plurality of resist removing portions 104a is formed on the sheet layer 102. In addition, similar to the second embodiment, after the patterned resist layer 104 is formed, an argon plasma applying process or a lightly etching process may be performed on the sheet layer.

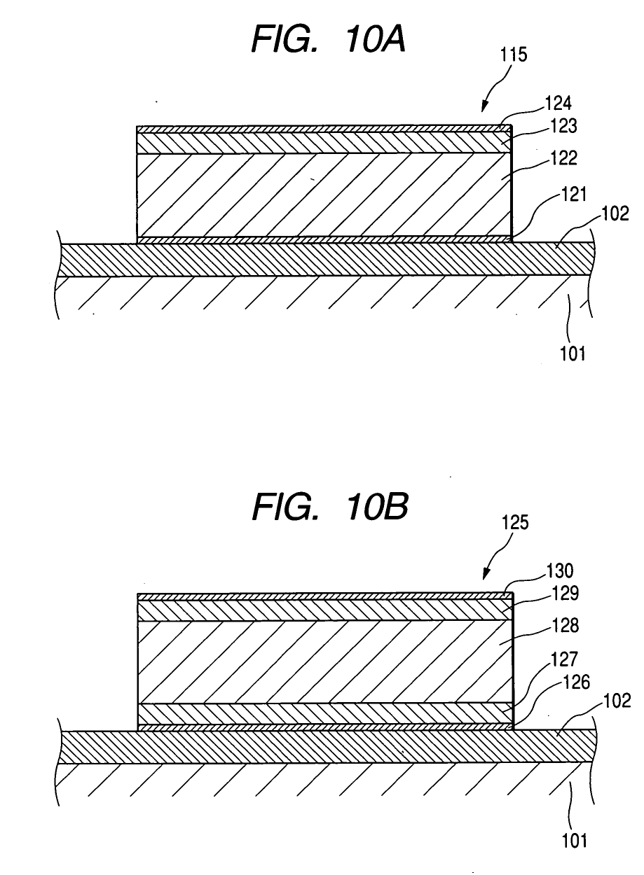

Subsequently, as shown in FIG. 9D, a wiring pattern 115 having a laminated structure of a plurality of metal layers is formed on the resist removing portions 104a by an electroplating method. FIG. 10A is an enlarged cross-sectional view illustrating an example of the wiring pattern 115. As shown in FIG. 10A, the wiring pattern 115 of the present embodiment includes an Au layer 121 formed on the sheet layer 102, a Cu layer 122 formed on the Au layer 121, an Ni layer 123 formed on the Cu layer 122, and an Au layer 124 formed on the Ni layer 123. As such, in the wiring pattern 115 of the present embodiment, the Au layers 121 and 124 are respectively formed on the Cu layer 122 and the Ni layer 123 in the thickness direction thereof. The thickness of the Au layer 121 is preferably in the range of 0.01 μm to 0.1 μm, and the thickness of the Cu layer 122 is preferably in the range of 5 μm to 10 μm. In addition, the thickness of the Ni layer 123 is preferably in the range of 2 μm to 4 μm, and the thickness of the Au layer 124 is preferably in the range of 0.1 μm to 0.5 μm. More specifically, preferably, the Au layer 121, the Cu layer 122, the Ni layer 123, and the Au layer 124 have 0.03 μm, 10 μm, 2 μm, and 0.2 μm in thickness, respectively. All the layers are formed by an electroplating method.

Further, the laminated structure of the wiring pattern is not limited to the shape shown in FIG. 10A. For example, as shown in FIG. 10B, a five-layered wiring pattern 125 composed of an Au layer 126, an Ni layer 127, a Cu layer 128, an Ni layer 129, and an Au layer 130 may be used.

Successively, as shown in FIG. 9E, the patterned resist layer 104 is removed by wet etching. Then, the wiring pattern 115 is formed on the sheet layer 102. The wiring pattern 115 includes a plurality of wiring line portions 115a and hollowed-out portions 115b provided adjacent to the wiring line portions 115a, similar to the second embodiment. For example, the wiring pattern 115 can have the same shape in plan view as that shown in FIG. 6.

Then, as shown in FIG. 9F, bumps 116 made of, for example, Au or Ag are formed on the wiring line portions 115a of the wiring pattern 115. In this way, the substrate 101 having the sheet layer 102 and the wiring pattern 115 on the surface 101a thereof is manufactured.

[Resin Layer Forming Process]

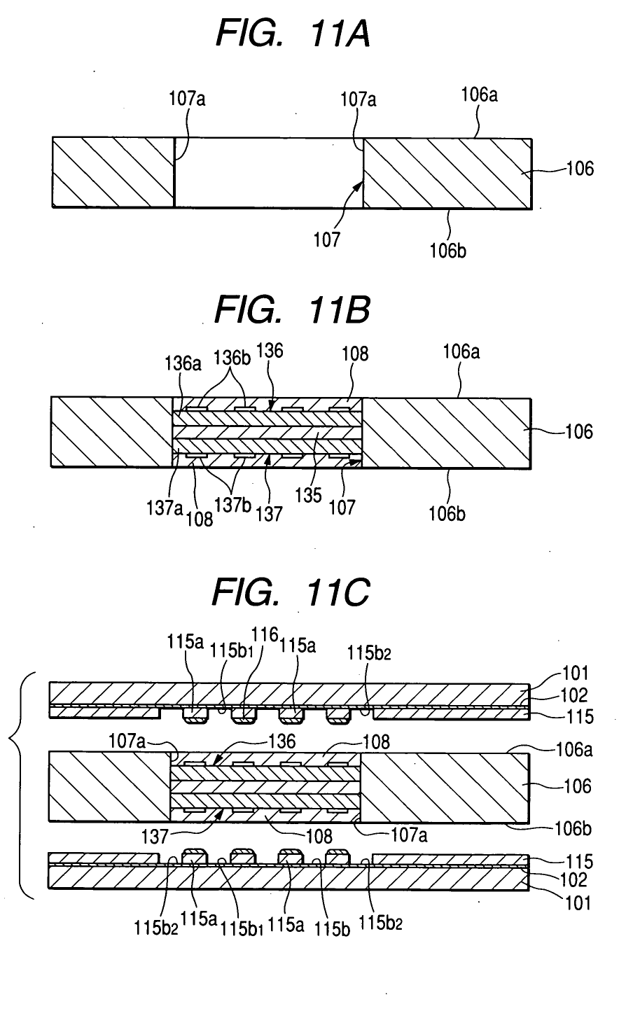

Next, the resin layer forming process will be described with reference to FIG. 11. In the resin layer forming process, as shown in FIG. 11A, first, the resin layer 106 is prepared, and a through hole 107 is provided in the resin layer 106 so as to pass through the one surface 106a and the other surface 106b of the resin layer 106.

Then, as shown in FIG. 11B, a plate-shaped spacer 135 made of a dielectric material is provided at the middle of the through hole 107 in the depth direction, and IC chips 136 and 137 (electronic components) are provided on both sides of the spacer 135 in the thickness direction. Then, the conductive particle containing resins 108 are filled in the through hole 107 to cover the IC chips 136 and 137. The IC chips 136 and 137 comprise chip bodies 136a and 136b and terminals 136b and 137b provided in the chip bodies 136a and 137a, respectively. The respective IC chips 136 and 137 are arranged such that the respective terminals 136b and 137b face the outer sides of the resin layer 106 in the thickness direction thereof. The conductive particle containing resins 108 are coated on the terminals 136b and 137b of the IC chips, respectively. In this way, the IC chips 136 and 137 and the conductive particle containing resins 108 are inserted into the through hole 107, thereby manufacturing the resin layer 106.

[Pressing Process]

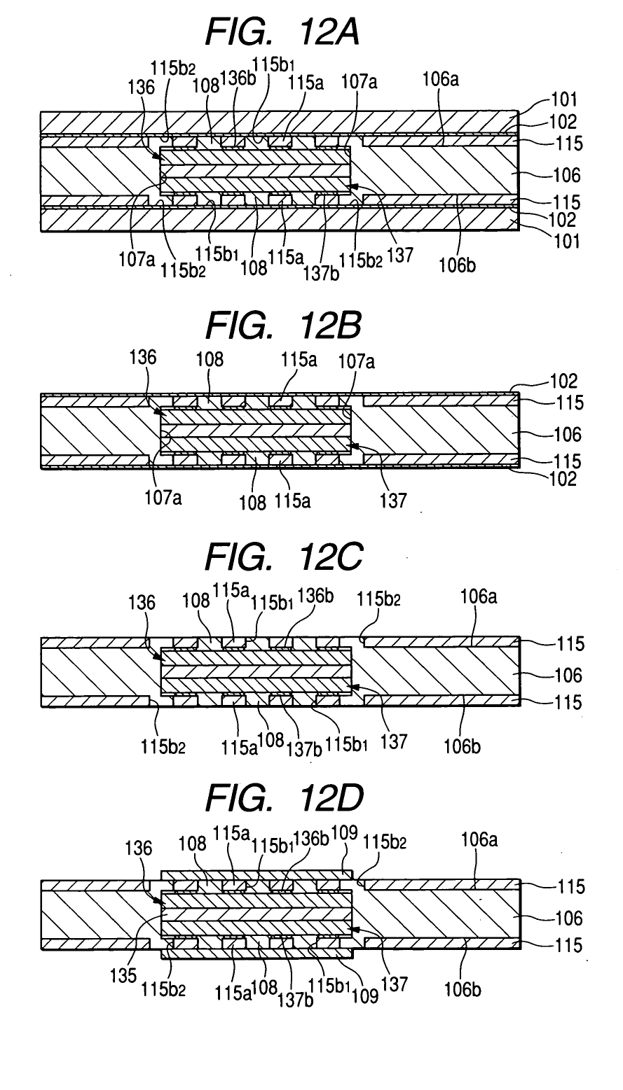

Next, the pressing process will be described with reference to FIGS. 11 and 12. First, as shown in FIG. 11C, two substrates 101 each having the wiring pattern 115 previously formed thereon are respectively arranged at both sides of the one surface 106a and the other surface 106b of the resin layer 106. In this case, the substrates 101 are arranged such that the hollowed-out portions 115b of the wiring pattern 115 of each substrate substantially overlap the portion where the conductive particle containing resin 108 is filled. More specifically, hollowed-out portions 115b₁ of the hollowed-out portions 115b positioned substantially at the center of FIG. 11C are provided at the more inner side than the circumferential edge 107a of the through hole. In addition, hollowed-out portions 115b₂ positioned at the outer circumferential side of the hollowed-out portions 115b₁ are provided to place across the inner side and the outer side of the circumferential edge 107a of the through hole.

Then, as shown in FIG. 12A, both the substrates 101 are thermally pressed against each other, with the resin layer 106 interposed therebetween, in the thickness direction of the resin layer 106. The resin layer 106 is transformed by the thermal pressing, so that the wiring patterns 115a and 115b are buries in the one surface 106a and the other surface 106b, respectively. At that time, a portion of the conductive particle containing resin 108 and a portion of the resin layer 106 are filled in the hollowed-out portions 115b of each wiring pattern 115. The conditions of the thermal pressing are the same as those in the second embodiment. In this way, the wiring patterns 115a and 115b are buried in the resin layer 106 and are then transferred thereto.

Referring to FIG. 12A again for the detailed description, similar to the second embodiment, the resin layer is transformed into a thin plate by the pressing, and then the conductive particle containing resin 108 is filled in the hollowed-out portions 115b₁ positioned substantially at the center of FIG. 12A. Meanwhile, a portion of the resin layer 106 is filled in the hollowed-out portions 115b₂ positioned at the outside of the hollowed-out portions 115b₁. When the resin layer 106 is made of a glass epoxy resin, only the epoxy resin is extruded from the resin layer and is then filled in the hollowed-out portions 115b₂. Here, a portion of the resin layer 106 can be filled into the hollowed-out portions 115b₂ because the resin layer is softened by the thermal pressing, so that a portion of the resin layer flows into the hollowed-out portions 115b₂ before the conductive particle containing resin 108 flows thereinto.

Further, a portion of the resin layer 106 and a portion of the conductive particle containing resin 108 are filled in the respective hollowed-out portions 115b, so that the wiring line portions 115a are buried in the conductive particle containing resin 108. At that time, the electrical connection between the wiring line portions 115a and the IC chips is secured by bringing the bumps 116 formed on the wiring line portions 115a into contact with the terminals 136b and 137b of the IC chips, or the bumps 116 are electrically connected to the terminals 136b and 137b through the conductive particle containing resin 108 interposed between the bumps 116 and the terminals 136b and 137b.

[Peeling Process and Etching Process]

Next, the peeling process will be described with reference to FIG. 12. In the peeling process, as shown in FIG. 12B, stress is applied between the substrates 101 and the resin layer 106 to peel off the substrates 101 from the resin layer 106. When the substrates 101 are peeled off from the sheet layers 102, the sheet layers 102 together with the wiring patterns 115 are transferred onto the resin layer 106.

Then, as shown in FIG. 12C, the sheet layer 102 transferred onto the resin layer 106 is removed by wet etching. Finally, as shown in FIG. 12D, the conductive resin layer 109 is coated to cover the hollowed-out portions 115b of the wiring pattern 115.

In this way, the circuit component module 200 of the present embodiment is manufactured.

[Circuit Component Module]

The circuit component module 200 shown in FIG. 12D includes the resin layer 106 and the wiring patterns 115 respectively buried in the one surface 106a and the other surface 106b of the resin layer 106, and the IC chips 136 and 137 provided in the resin layer 106. The through hole 107 is provided in the resin layer 106, and the IC chips 136 and 137 and the conductive particle containing resin 108 are inserted in the through hole 107. In addition, each wiring pattern 115 is composed of a plurality of wiring line portions 115a made of Cu, and the hollowed-out portions 115b are formed in the respective wiring line portions 115a. Further, the wiring line portions 115a are connected to the terminals 136b and 137b of IC chips through the bumps 116 and the conductive particle containing resin 108. Furthermore, the conductive particle containing resin 108 is filled in the hollowed-out portions 115b₁ of the hollowed-out portions 115b provided on the through hole 107, and a portion of the resin layer 106 is filled in the hollowed-out portions 115b₂ provided at the outside of the circumferential edge 107a of the through hole 107.

According to the circuit component module 200 of the present embodiment and the method of manufacturing the same, the IC chips 136 and 137 are provided in the through hole 107, which makes it possible to reduce the thickness of the circuit component module 200. In addition, since the wiring line portions 115a having the above-mentioned structure are electrically connected to the terminals 136b and 137b of the IC chips through the conductive particle containing resin 108 interposed therebetween, it is possible to improve the reliability of the circuit component module 200.

Further, since the bumps 116 are provided on the wiring line portions 115a, it is possible to more reliably perform the electrical connection between the wiring line portions 115a and the IC chips 136 and 137.

Furthermore, according to the above-mentioned circuit component module 200 and the method of manufacturing the same, it is possible to obtain the same effects as those in the circuit component module of the second embodiment.

According to the circuit component module of the present invention, since components are covered with the resin layer, the components can be protected from external environments. In addition, since components are arranged between wiring lines, it is possible to reduce the thickness and weight of a circuit component module. When the circuit component module is used as a component circuit board of a portable electronic apparatus, it contributes to realizing a portable electronic apparatus having a small size and light weight.

Further, according to the method of manufacturing the circuit component module of the present invention, since the wiring line portions are buried in the resin layer, there is no fear that the wiring line portions will be etched in the next etching step. Therefore, it is possible to prevent the reduction of the line width of the wiring line portions and thus to realize a line and space (L/S) of 10 μm/10 μm, which has been not achieved in the conventional transferring method.

Moreover, according to the method of manufacturing the circuit component module of the present invention, it is possible to raise the bonding strength between the wiring line portions and the conductive particle containing resin, and thus to improve the reliability of the circuit component module.

1. A circuit component module comprising:
a resin layer;
a component buried in the resin layer; and
wiring patterns buried in one surface or both surfaces of the resin layer,
wherein a through hole is provided in the resin layer to pass through both the surfaces thereof, and a conductive particle containing resin or a cylindrical bump formed by laminating a plurality of bumps is filled in the through hole.

2. A circuit component module comprising:
a resin layer; and
wiring patterns buried in one surface or both surfaces of the resin layer,
wherein a through hole is provided in the resin layer to pass through both the surfaces thereof, and a conductive particle containing resin is filled in the through hole,
each of the wiring patterns is composed of a plurality of wiring line portions made of conductive metal, and hollowed-out portions are formed in the respective wiring line portions,
the conductive particle containing resin is filled in some of the hollowed-out portions arranged on the through hole, and a portion of the resin layer is filled in the hollowed-out portions arranged at the outside of a circumferential edge of the through hole.

3. The circuit component module according to claim 2,
wherein electronic components are provided in the through hole, and the conductive particle containing resin is formed on terminals of the electronic components, and
some of the plurality of wiring line portions provided on the through hole are electrically connected to the terminals of the electronic components through the conductive particle containing resin.

4. The circuit component module according to claim 2,
wherein bumps are formed on the wiring line portions provided in the through hole, and the bumps are connected to the terminals of the electronic components.

5. A method of manufacturing a circuit component module comprising:
a step of forming a resist pattern on one surface of a substrate;
a step of coating a metallic material on portions other than the resist pattern;
a step of removing the resist to form wiring lines by the coating;
a step of mounting a component on the wiring lines;
a step of forming a resin layer on the substrate such that the component and the wiring lines are buried in the resin layer; and
a step of peeling the substrate from the resin layer.

6. A method of manufacturing a circuit component module comprising:
a step of respectively forming resist patterns on surfaces of a first substrate and a second substrate opposite to each other;
a step of coating a metallic material on portions other than the resist patterns;
a step of removing the resists to form first wiring lines and second wiring lines by the coating;
a step of mounting components on the first and second wiring lines, respectively;
a step of forming a resin layer between the first and second substrates such that the components and the first and second wiring lines are buried in the resin layer; and
a step of peeling the first and second substrates from the resin layer.

7. A method of manufacturing a circuit component module comprising:
a step of forming a wiring pattern in which hollowed-out portions are provided in a plurality of wiring line portions; the wiring pattern forming step including the sub-steps of: forming a sheet layer on one surface of a substrate; forming a resist pattern on the sheet layer; coating a metallic material on portions other than the resist pattern to form the plurality of wiring line portions; and removing the resist pattern;
a step of providing a through hole in the resin layer to pass through both surfaces thereof and of filling a conductive particle containing resin in the through hole;
a step of pressing the resin layer against the wiring pattern such that the wiring line portions are buried in the resin layer, such that the conductive particle containing resin is filled in the hollowed-out portions provided on the through hole, and such that a portion of the resin layer is filled in the hollowed-out portions provided at the outside of a circumferential edge of the through hole;
a step of peeling the substrate and the sheet layer from the resin layer.

8. The method of manufacturing a circuit component module according to claim 5,
wherein, in the wiring line forming step, after the resist pattern is formed, an argon plasma is radiated to the one surface of the substrate, and then a metallic material is coated on portions other than the resist pattern to form a plurality of wiring line portions.

9. The method of manufacturing a circuit component module according to claim 6,
wherein, in the wiring line forming step, after the resist pattern is formed, an argon plasma is radiated to the one surface of the substrate, and then a metallic material is coated on portions other than the resist pattern to form a plurality of wiring line portions.

10. The method of manufacturing a circuit component module according to claim 7,
wherein, in the wiring line forming step, after the resist pattern is formed, an argon plasma is radiated to the one surface of the substrate, and then a metallic material is coated on portions other than the resist pattern to form a plurality of wiring line portions.

11. The method of manufacturing a circuit component module according to claim 7, further comprising:
a step of, after the peeling step, etching the sheet layer transferred onto the resin layer to remove it.

12. The method of manufacturing a circuit component module according to claim 7,
wherein, in the resin layer forming step, electronic components are provided in the through hole of the resin layer, and the conductive particle containing resin is formed on terminals of the electronic components, and
in the pressing step, some of the plurality of wiring line portions provided on the through hole are electrically connected to the terminals of the electronic components through the conductive particle containing resin interposed therebetween.

13. The method of manufacturing a circuit component module according to claim 12,
wherein bumps are formed on the wiring line portions provided in the through hole, and the bumps are connected to the terminals of the electronic components.
